(19) United States
(12) Patent Application Publication
(10) Pub. No.: US 2024/0226941 A1
(43) Pub. Date: Jul. 11, 2024

(54) APPARATUS FOR SUPPLYING TREATING MATERIAL AND SYSTEM FOR SUPPLYING THE TREATING MATERIAL

(71) Applicant: SAMSUNG ELECTRONICS CO., LTD., Suwon-si (KR)

(72) Inventors: Jun Hee LEE, Suwon-si (KR); Kyoung Whan OH, Suwon-si (KR); Ho Kyun KIM, Suwon-si (KR)

(21) Appl. No.: 18/502,055

(22) Filed: Nov. 5, 2023

(30) Foreign Application Priority Data
Jan. 9, 2023 (KR) 10-2023-0002842

(51) Int. Cl. B05B 12/00; B05B 1/08

(52) U.S. Cl. CPC B05B 12/006; B05B 1/08

(57) ABSTRACT

An apparatus for supplying a treating material includes a nozzle discharging the treating material onto a substrate. A flow pipe channels the treating material to the nozzle. A cut-off valve connected to the flow pipe controls the discharge the treating material. A first controller controls a first opening and closing of the cut-off valve. A second controller controls a second opening and closing of the cut-off valve. The second opening and closing of the cut-off valve is performed by the second controller after a delay time has elapsed after the first opening and closing is completed.

### CROSS-REFERENCE TO RELATED APPLICATION

This application claims priority under 35 U.S.C. 119 to Korean Patent Application No. 10-2023-0002842 filed on Jan. 9, 2023 in the Korean Intellectual Property Office, the contents of which is herein incorporated by reference in its entirety.

### Technical Field

The present disclosure relates to a treatment apparatus and, more specifically, to an apparatus for supplying a treating material and a system for supplying the treating material.

### Discussion of the Related Art

Photolithography is a process for forming a desired pattern on a wafer that often involves coating a wafer with a photoresist, using light to expose a desired pattern, developing the exposed photoresist, and then using an etchant to finalize the pattern. The photolithography process therefore requires multiple different facilities such as a spinner facility for coating the wafer and an exposure facility that may be used to pattern and develop the wafer.

In such a photolithography process, various treating materials other than photoresist (PR) may also be discharged onto a substrate. When a cut-off valve controlling the discharge of the treating material is opened and closed at a suboptimal speed, there is a problem in that the discharge of the treating material is not precisely controlled, and thus defects of the semiconductor device occur.

### SUMMARY

An apparatus for supplying a treating material includes a nozzle discharging the treating material onto a substrate. A flow pipe channels the treating material to the nozzle. A cut-off valve is connected to the flow pipe and controls discharge of the treating material through the nozzle. A first controller controls a first opening and closing of the cut-off valve. A second controller controls a second opening and closing of the cut-off valve. The second opening and closing of the cut-off valve is performed by the second controller after a delay time has elapsed after the first opening and closing is completed.

An apparatus for supplying a treating material includes a nozzle discharging the treating material onto a substrate. A flow pipe channels the treating material to the nozzle. A cut-off valve connected to the flow pipe controls a flow of the treating material by adjusting a flow rate of air. A sensor is disposed at an end portion of the nozzle. A first controller controls a closing speed of the cut-off valve. A second controller controls an opening time point of the cut-off valve. A first pressure wave is generated at a first closing time point of the cut-off valve, and a second pressure wave having a phase difference with respect to the first pressure wave is generated at a second closing time point of the cut-off valve.

A system for supplying a treating material including an apparatus supplying the treating material includes a nozzle discharging the treating material onto a substrate. A flow pipe channels the treating material to the nozzle. A cut-off valve connected to the flow pipe controls discharge the treating material. A sensor is disposed at an end portion of the nozzle. A first controller controls a closing speed of the cut-off valve. A second controller controls a closing time point of the cut-off valve. A first pressure wave is generated by a first closing of the cut-off valve. A second_first pressure wave having a first phase difference with respect to the first pressure wave is generated by a second closing of the cut-off valve. The first pressure wave and the second_first pressure wave combine to generate a third_first pressure wave. The second controller generates a second_second pressure wave having a second phase difference with respect to the first pressure wave by receiving data on vibration of the third_first pressure wave from the sensor. The first pressure wave and the second_second pressure wave combine to generate a third_second pressure wave.

### BRIEF DESCRIPTION OF THE DRAWINGS

The above and other aspects and features of the present disclosure will become more apparent by describing in detail embodiments thereof with reference to the attached drawings, in which:

FIG. 1 is a cross-sectional view schematically illustrating an apparatus for manufacturing a semiconductor device according to some embodiments of the present disclosure;

FIG. 2 is a plan view schematically illustrating the apparatus for manufacturing a semiconductor device according to some embodiments of the present disclosure;

FIG. 3 is a view schematically illustrating a treating chamber of the apparatus for manufacturing a semiconductor device according to some embodiments of the present disclosure;

FIG. 4 is a view schematically illustrating a treating material supply unit of the treating chamber according to some embodiments of the present disclosure;

FIG. 5 is a view for describing an operation of a cut-off valve according to some embodiments of the present disclosure;

FIG. 6 is a view for describing a pressure wave generated by the operation of the cut-off valve according to some embodiments of the present disclosure;

FIG. 7 is a view for describing an operation of a cut-off valve according to some embodiments of the present disclosure;

FIG. 8 is a view for describing a pressure wave generated by the operation of the cut-off valve according to some embodiments of the present disclosure; and

FIGS. 9 to 11 are views for describing control of cutoff characteristics according to some embodiments of the present disclosure.

### DETAILED DESCRIPTION OF THE EMBODIMENTS

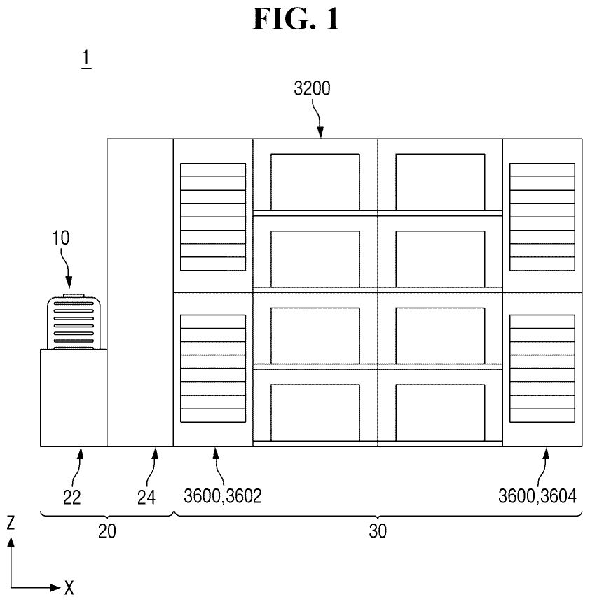

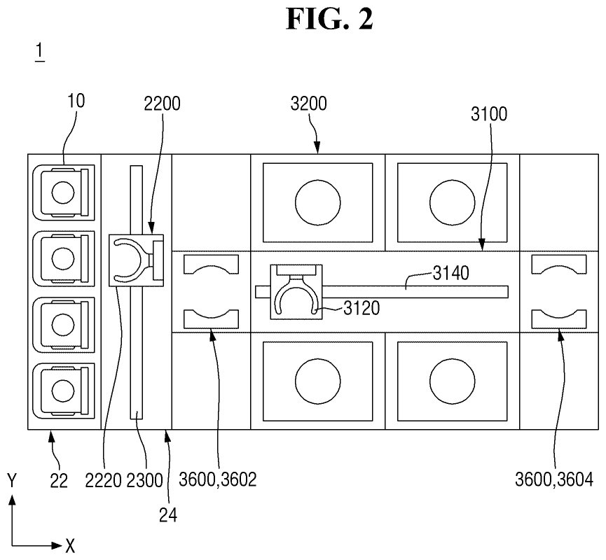

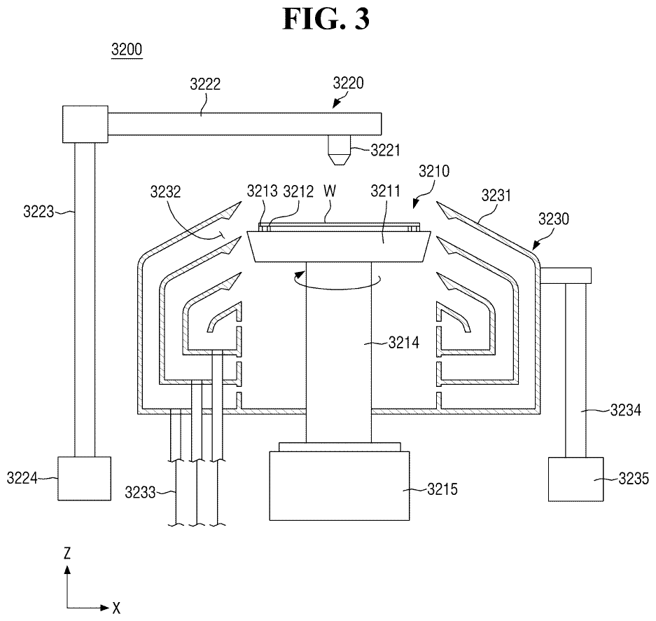

FIG. 1 is a cross-sectional view schematically illustrating an apparatus for manufacturing a semiconductor device according to some embodiments of the present disclosure. FIG. 2 is a plan view schematically illustrating the apparatus for manufacturing a semiconductor device according to some embodiments of the present disclosure. FIG. 3 is a view schematically illustrating a treating chamber of the apparatus for manufacturing a semiconductor device according to some embodiments of the present disclosure.

An apparatus 1 for manufacturing a semiconductor device may include an index module 20 and a treating module 30. According to some embodiments of the present disclosure, the index module 20 and the treating module 30 may be sequentially arranged in a line. Hereinafter, a direction in which the index module 20 and the treating module 30 are arranged may be referred to as a first direction X, a direction crossing the first direction X when viewed from above may be referred to as a second direction Y, and a direction crossing both the first direction X and the second direction Y may be referred to as a third direction Z.

The index module 20 may transfer a substrate W from a container 10 in which the substrate W is accommodated to the treating module 30 and may accommodate the substrate W after the treatment has been completed into the container 10. The index module 20 may extend in the second direction Y. The index module 20 may include a load port 22 and an index frame 24. With respect to the index frame 24, the load port 22 may be disposed on an opposite side of the treating module 30. The container 10 in which the substrates W are accommodated may be disposed on the load port 22. A plurality of load ports 22 may be provided, and the plurality of load ports 22 may be disposed along the second direction Y.

The container 10 may be an airtight container such as a front open unified pod (FOUP). The container 10 may be disposed on the load port 22 by a transport means such as an overhead transfer, an overhead conveyor, or an automatic guided vehicle, or by an operator.

An index robot 2200 may be disposed inside the index frame 24. A guide rail 2300 having a longitudinal direction in the second direction Y may be disposed in the index frame 24, and the index robot 2200 may be movable on the guide rail 2300. The index robot 2200 may include a hand on which the substrate W is disposed, and the hand may move forward and backward, rotate about an axis in the third direction Z, and move along the third direction Z.

According to some embodiments, the treating module 30 may perform a treatment process on the substrate W. For example, the treating module 30 may perform a photolithography process on the substrate W.

The treating module 30 may include a treating block that performs the treatment process on the substrate W. A plurality of treating blocks may be provided, and the plurality of treating blocks may be stacked on top of each other. Each of the treating blocks may include a transfer chamber 3100, a treating chamber 3200, and a buffer chamber 3600.

The transfer chamber 3100 may transfer the substrate W within the treating module 30. The transfer chamber 3100 may extend parallel to the first direction X. A transfer unit 3120 may be disposed in the transfer chamber 3100. The transfer unit 3120 may transfer the substrate W between the treating chambers 3200.

The transfer unit 3120 may include a base and an arm. The arm may have a shape similar to an annular ring shape in which a portion of a circumference is bent. The arm may extend from the base. A plurality of arms may support an edge area of the substrate W.

For example, the arm may move forward and backward, rotate about an axis in the third direction Z, and move along the third direction Z. A guide rail 3140 extending parallel to the first direction X may be disposed in the transfer chamber 3100, and the transfer unit 3120 may be movable on the guide rail 3140.

The treating chamber 3200, according to some embodiments of the present disclosure, may be used for a photolithography process of forming a desired pattern on the substrate W such as a silicon wafer. The photolithography process is performed in a spinner facility that is connected to an exposure facility and continuously treats a photoresist (PR) coating process, an exposure process, and a developing process. The spinner facility may include process facilities capable of performing a photoresist (PR) coating process, a baking process, a rinsing process, and a developing process.

The treating chamber 3200 may be disposed on one side of the transfer chamber 3100. The treating chamber 3200 may include the process facilities capable of performing the above-described photoresist (PR) coating process, baking process, rinsing process, and developing process. The respective facilities of the treating chamber 3200 may be stacked with each other. The respective facilities of the treating chamber 3200 may face each other with the transfer chamber 3100 interposed therebetween. However, the technical idea of the present disclosure is not necessarily limited thereto, and the respective facilities of the treating chamber 3200 may be changed in consideration of a footprint, process efficiency, and the like of the apparatus.

Referring to FIG. 3, the treating chamber 3200 may process the substrate W by applying a treating material, for example, a liquid chemical to the substrate W. The treating chamber 3200 may include a housing, a support unit 3210, a treating material supply unit 3220, and a recovery unit 3230. The housing of the treating chamber 3200 may provide a treatment space in which the substrate W is treated.

The support unit 3210 may support the substrate W. The support unit 3210 may rotate the supported substrate W. The support unit 3210 may include a support plate 3211, a support pin 3212, a chuck pin 3213, a rotation shaft 3214, and a rotation actuator 3215. The substrate W may be seated on the support plate 3211, and the support plate 3211 may have an upper surface having the same shape as or a similar shape to that of the substrate W.

The support pin 3212 and the chuck pin 3213 may be disposed on the upper surface of the support plate 3211. The support pin 3212 may support a bottom surface of the substrate W. The support pin 3212 may protrude upward from the upper surface of the support plate 3211. The chuck pin 3213 may fix the supported substrate W. The chuck pin 3213 may have a larger diameter than the support pin 3212.

The chuck pin 3213 may support a side portion of the supported substrate W. This may prevent the rotating substrate W from being deviated in a lateral direction by a rotational force. The rotation shaft 3214 may be connected to a lower portion of the support plate 3211. The rotation shaft 3214 may rotate the support plate 3211 by receiving the rotational force from the rotation actuator 3215. Accordingly, the substrate W seated on the support plate 3211 may be rotated. The chuck pin 3213 may prevent the substrate W from deviating from its original position.

The treating material supply unit 3220 may spray the treating material onto the substrate W. The treating material may include various liquid chemicals other than photoresist (PR). For example, the treating material may be thinner, positive tone development (PTD), negative tone development (NTD), deionized water (DIW), and the like, but is not necessarily limited thereto.

The treating material supply unit 3220 may include a nozzle 3221, a nozzle bar 3222, a nozzle shaft 3223, and a nozzle shaft actuator 3224. The nozzle 3221 may supply the treating material to the substrate W seated on the support plate 3211. The nozzle 3221 may be formed on a bottom surface of one end of the nozzle bar 3222. The nozzle bar 3222 may be coupled to the nozzle shaft 3223. The nozzle shaft 3223 may be elevated or rotated. The nozzle shaft actuator 3224 may adjust a position of the nozzle 3221 by elevating or rotating the nozzle shaft 3223.

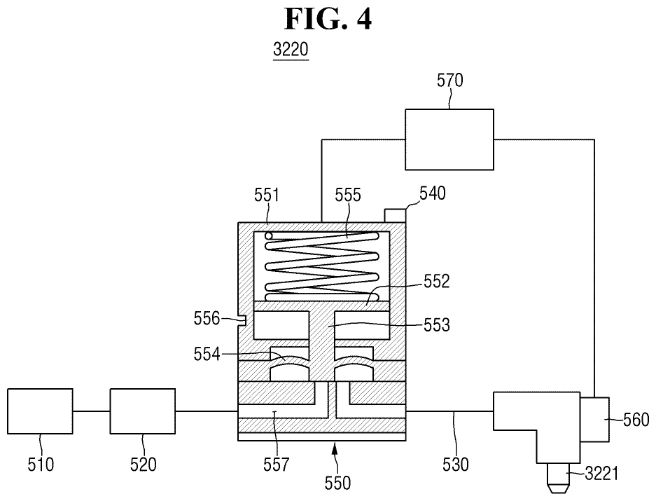

The nozzle 3221 may be an area from which the above-described treating material is sprayed. The nozzle 3221 may be connected to a treating material supply source (510 in FIG. 4) for supplying the above-described treating material. A flow pipe (530 in FIG. 4) may be connected to the treating material supply source (510 in FIG. 4) for supplying the treating material. A cut-off valve (550 in FIG. 4) for adjusting the supply of the treating material may be connected to the flow pipe (530 in FIG. 4). Details of the treating material supply source (510 in FIG. 4), the flow pipe (530 in FIG. 4), and the cut-off valve (550 in FIG. 4) will be described later.

The recovery unit 3230 may include a recovery cylinder 3231, a recovery line 3233, an elevating bar 3234, and an elevating actuator 3235. The recovery cylinder 3231 may have an annular ring shape surrounding the support plate 3211. A plurality of recovery cylinders 3231 may be provided. The plurality of recovery cylinders 3231 may have a ring shape sequentially away from the support plate 3211 when viewed from above. The recovery cylinder 3231 may have a greater height as the recovery cylinder 3231 is farther from the support plate 3211. A recovery hole 3232 through which the treating material scattered from the substrate W is introduced may be formed in a space between the recovery cylinders 3231. The recovery line 3233 may be formed on a lower surface of the recovery cylinder 3231. The elevating bar 3234 may be connected to the recovery cylinder 3231.

The elevating bar 3234 may move the recovery cylinder 3231 up and down by receiving power from the elevating actuator 3235. The elevating bar 3234 may be connected to the recovery cylinder 3231 disposed at the outermost portion when there are a plurality of recovery cylinders 3231. The elevating actuator 3235 may adjust the recovery hole 3232 of the plurality of recovery holes 3232 into which the scattered treating materials are introduced by elevating the recovery cylinder 3231 through the elevating bar 3234.

A plurality of buffer chambers 3600 may be provided. Some of the buffer chambers 3600 may be disposed between the index module 20 and the transfer chamber 3100. Hereinafter, such buffer chambers are referred to as front buffers 3602. A plurality of front buffers 3602 may be stacked on top of each other in a vertical direction. Others of the buffer chambers 3602 and 3604 may be disposed outside the transfer chamber 3100 in the second direction Y. Hereinafter, such buffer chambers are referred to as rear buffers 3604. A plurality of rear buffers 3604 may be stacked on top of each other in the vertical direction. Each of the front buffers 3602 and the rear buffers 3604 may temporarily store the plurality of substrates W. The substrate W stored in the front buffer 3602 may be put in or taken out by the index robot 2200 and the transfer unit 3120. The substrate W stored in the rear buffer 3604 may be put in or taken out by the transfer unit 3120.

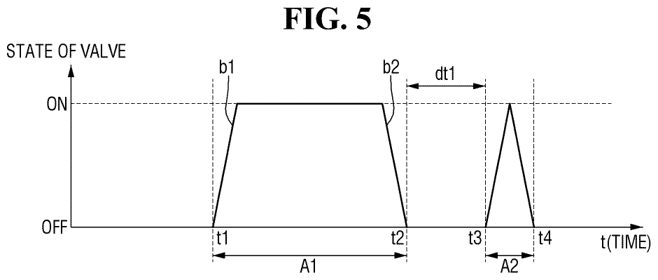

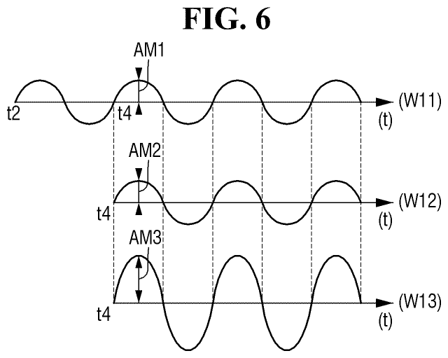

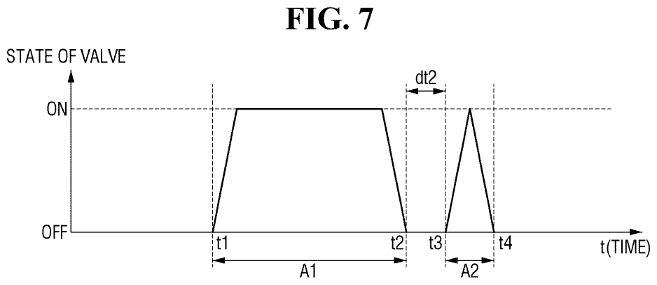

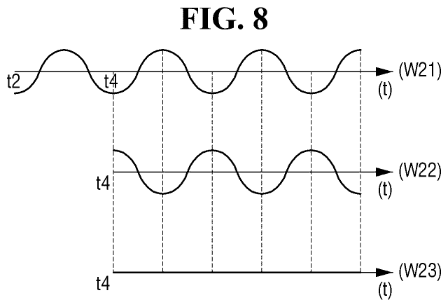

FIG. 4 is a view schematically illustrating a treating material supply unit of the treating chamber according to some embodiments of the present disclosure. FIG. 5 is a view for describing an operation of a cut-off valve according to some embodiments of the present disclosure. FIG. 6 is a view for describing a pressure wave generated by the operation of the cut-off valve according to some embodiments of the present disclosure. FIG. 7 is a view for describing an operation of a cut-off valve according to some embodiments of the present disclosure. FIG. 8 is a view for describing a pressure wave generated by the operation of the cut-off valve according to some embodiments of the present disclosure.

The treating material supply unit 3220, according to some embodiments of the present disclosure, may include a nozzle 3221, a treating material supply source 510, a pump 520, a flow pipe 530, a first controller 540, a cut-off valve 550, a sensor 560, and a second controller 570.

These controllers and others, as described herein, may be embodied as a logical device, such as a microprocessor or logic chip, programmed to send a desired electrical signal at a desired time and to control a cut-off valve, or other element, by initiating a motor and/or gear system, in accordance with the sent electrical signals, to deliver a necessary moving force to close and/or open the cut-off valve.

Referring to FIG. 4, the treating material supply source 510 is connected to the nozzle 3221 through the flow pipe 530. The pump 520 may be disposed in front of the treating material supply unit 3220.

The treating material supplied from the treating material supply source 510 is pressurized by the pump 520, and the pressurized treating material passes through the cut-off valve 550 and then is discharged onto the substrate W through the nozzle 3221.

The cut-off valve 550 opens and closes a flow of the pressurized treating material so that the treating material is discharged to the nozzle 3221 by adjusting a flow rate of air. The cut-off valve 550 has a valve body 551. A piston 552 that is movable in the vertical direction is installed in the valve body 551. A shaft 553 is coupled to a lower surface of the piston 552 in the vertical direction, and a diaphragm 554 is coupled to a lower end of the shaft 553. A spring 555 is installed on the piston 552. A lower end of the spring 555 is in contact with an upper surface of the piston 552, and an upper end of the spring 555 is in contact with an inner surface of an upper wall of the valve body 551.

When air is introduced into a lower portion of the piston 552 through an inlet 556 formed on a sidewall of the valve body 551, the piston 552 moves upward. In addition, when the air is exhausted through the inlet 556, the piston 552 moves downward by a restoring force of the spring 555 installed on the piston 552. In this way, as the piston 552 moves in the vertical direction and the diaphragm 554 coupled to the shaft 553 on the lower portion of the piston 552 moves vertically according to the vertical movement of the piston 552, a passage 557 formed in the valve body 551 is opened and closed.

A controller may be connected to the inlet 556 of the cut-off valve 550. The controller adjusts an amount of air flowing in/out through the inlet 556 of the cut-off valve 550.

The treating material supply unit 3220, according to some embodiments of the present disclosure, may further include a suck-back valve. The suck-back valve may prevent spilling of the treating material by suctioning and retracting a certain amount of the treating material present at the tip of the nozzle 3221 after the treating material is discharged.

The first controller 540 may control an opening and closing speed of the cut-off valve 550 in a first opening and closing section A1 to be described later. The first controller 540 is in the form of a knob for controlling a discharge speed of the treating material, and may be manually controlled by a user. However, the shape and position of the first controller 540 might not necessarily be limited to those illustrated herein.

The sensor 560 may be disposed at an end portion of nozzle 3221. The sensor 560 may be attached to the end portion of the nozzle 3221 to measure vibration or pressure of a pressure wave generated by a water hammering phenomenon to be described later. For example, the sensor 560 may measure vibration of a pressure wave generated in a second opening and closing section A2 of the cut-off valve 550.

The second controller 570 may receive data about the vibration of the pressure wave measured from the sensor 560 and adjust a timing at which the second opening and closing section A2 is generated. Accordingly, it is possible to control a second opening and closing time point t3 at which the second opening and closing section A2 starts.

Referring to FIG. 5, the cut-off valve 550 may have a first opening and closing section A1 and a second opening and closing section A2.

The first opening and closing section A1 may refer to a section from a first opening time point t1 to a first closing time point t2. The first opening and closing section A1 refers to a section in which the cut-off valve 550 is firstly opened and closed.

At the first closing time point t2 of the first opening and closing section A1, a water hammering phenomenon may occur in both directions with respect to the cut-off valve 550 along the flow pipe 530. A first pressure wave (W11 in FIG. 6) may be generated inside the flow pipe 530 according to the water hammering phenomenon. The magnitude of the first pressure wave (W11 in FIG. 6) is proportional to a first closing speed b2, and as a result, the treating material may be excessively vibrated, which causes a cut-off defect.

Since the first opening speed b1 and the first closing speed b2 of the first pressure wave (W11 in FIG. 6) are set by the user, such speeds may be constant. For example, the first opening speed b1 and the first closing speed b2, which mean a slope of a graph of the first opening and closing section A1, may be constant.

The second opening and closing section A2 may refer to a section from a second opening time point t3 to a second closing time point t4. The second opening and closing section A2 refers to a section in which the cut-off valve 550 is secondly opened and closed.

At the second closing time point t4 of the second opening and closing section A2, a second pressure wave (W12 in FIG. 6) may be generated. For example, the second pressure wave (W12 in FIG. 6) may be generated when the cut-off valve 550 receives a signal from the second controller 570 to open (ON) or close (OFF) the valve.

The second opening time point t3 may refer to a time point after a predetermined first delay time dt1 has elapsed from the first closing time point t2. For example, the first delay time dt1 may refer to a time difference between the first closing time point t2 and the second opening time point t3.

For example, the second opening and closing of the cut-off valve 550 is performed by the second controller 570 after the first delay time dt1 has elapsed after the first opening and closing is completed. For example, the second controller 570 may determine only timings of the second opening and the second closing by adjusting the above-described time difference (i.e., a phase difference described later) without controlling a second opening speed and a second closing speed of the second opening and closing section A2.

A third pressure wave (W13 in FIG. 6) may be generated when the first and second pressure waves (W11 and W12 in FIG. 6) overlap each other (e.g., when the first and second pressure waves combine).

Referring to FIG. 6, the first pressure wave W11 may have a first amplitude AM1 and a first frequency at the first closing time point t2. The second pressure wave W12 may have a second amplitude AM2 and a second frequency at the second closing time point t4. A phase difference between the first pressure wave W11 and the second pressure wave W12 may be generated according to the above-described first delay time dt1.

For example, phases of the first pressure wave W11 and the second pressure wave W12 may be identical to each other by controlling the above-described first delay time dt1. Accordingly, the third pressure wave W13 may be formed by constructive interference of the first and second pressure waves W11 and W12. The third pressure wave W13 may have a third amplitude AM3 different from each of the first and second amplitudes AM1 and AM2. For example, the third amplitude AM3 may be greater than each of the first and second amplitudes AM1 and AM2.

Referring to FIG. 7, the second opening time point t3 may refer to a time point after a second delay time dt2 shorter than the first delay time dt1 has elapsed from the first closing time point t2. For example, the second opening and closing of the cut-off valve 550 is performed by the second controller 570 after the second delay time dt2 has elapsed after the first opening and closing is completed.

The second delay time dt2 may be different from the first delay time dt1 and is not necessarily limited to being shorter than the first delay time dt1.

Referring to FIG. 8, a phase difference between a first pressure wave W21 and a second pressure wave W22 may be generated differently from that illustrated in FIG. 6 according to the second delay time dt2.

For example, the phases of the first pressure wave W21 and the second pressure wave W22 may be opposite to each other by controlling the above-described second delay time dt2. Accordingly, a third pressure wave W23 may be formed by destructive interference of the first and second pressure waves W21 and W22.

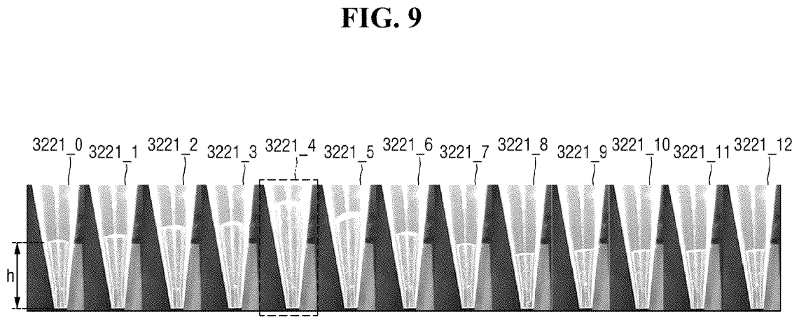

FIGS. 9 to 11 are views for describing control of cutoff characteristics according to some embodiments of the present disclosure.

FIG. 9 is a view illustrating a cut-off height h of each of nozzles 3221_0 to 3221_12 by setting delay times to be different from each other. In some embodiments of the present disclosure, the cut-off height h may refer to a height of the treating material from the lower end of the nozzle 3221.

A zero-th nozzle 3221_0 in FIG. 9 illustrates a cutoff height h measured when the cut-off valve 550 is firstly opened and closed without setting the delay time. Each of the first to twelfth nozzles 3221_1 to 3221_12 illustrates a cutoff height measured while changing the first delay time dt1 so that the constructive interference of the first and second pressure waves (W11 and W12 in FIG. 6) occurs.

A fourth nozzle 3221_4 in FIG. 9 illustrates a cutoff height h when maximum constructive interference occurs. For example, the second controller 570 may control the cutoff height to be maximized while changing the first delay time dt1 so that the constructive interference of the first and second pressure waves (W11 and W12 in FIG. 6) occurs.

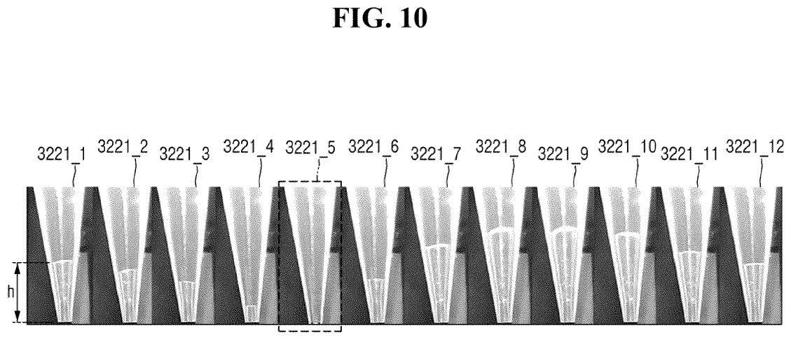

FIG. 10 is a view illustrating a cut-off height h at an end portion of each of nozzles 3221_1 to 3221_12 by setting delay times to be different from each other.

Referring to FIG. 10, each of the first to twelfth nozzles 3221_1 to 3221_12 illustrates a cutoff height measured while changing the second delay time dt2 so that the destructive interference of the first and second pressure waves (W21 and W22 in FIG. 8) occurs.

A fifth nozzle 3221_5 in FIG. 10 illustrates a cutoff height when maximum destructive interference occurs. For example, the second controller 570 may control the cutoff height to be minimized while changing the second delay time dt2 so that the destructive interference of the first and second pressure waves (W21 and W22 in FIG. 8) occurs.

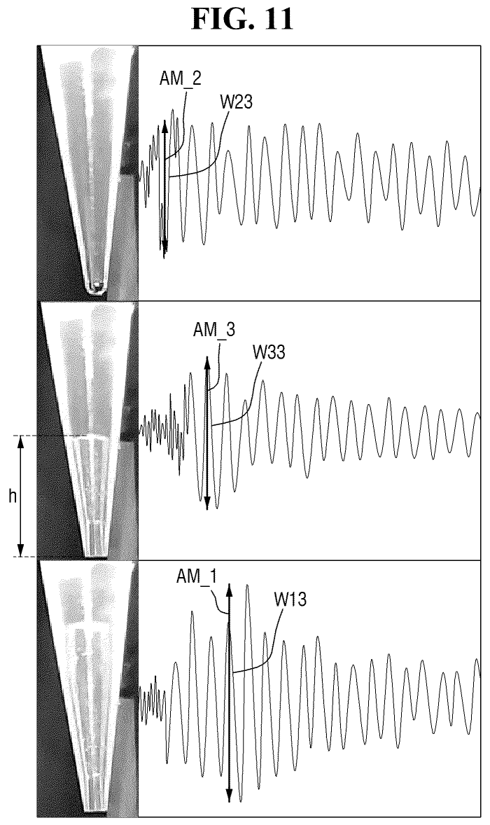

Referring to FIGS. 4 and 11, by the second controller 570, the cut-off valve 550 may be controlled to achieve a desired cutoff height h by receiving feedback on a vibration state.

As an example, by the first closing of the cut-off valve 550, the first pressure wave (W11 in FIG. 6) may be generated at the first closing time point t2, and by the second closing of the cut-off valve 550, a second_first pressure wave (W12 in FIG. 6) having a first phase difference with the first pressure wave (W11 in FIG. 6) may be generated at the second closing time point t4. Accordingly, the first pressure wave W11 and the second_first pressure wave (W11 and W12 in FIG. 6) overlap each other to generate a third_first pressure wave W13 illustrated in FIG. 11.

Since vibration intensity AM_1 of the third_first pressure wave W13 is excessively high, excessive cutoff characteristics may appear. Accordingly, the second controller 570 may generate a second_second pressure wave having a second phase difference with the first pressure wave (W11 in FIG. 6) by receiving data on the vibration of the third_first pressure wave W13, for example, the amplitude or frequency, from the sensor 560. In this case, the second phase difference may be different from the first phase difference. Accordingly, the first pressure wave W11 and the second_second pressure wave overlap each other to generate a third_third pressure wave W33 illustrated in FIG. 11.

Since the third_third pressure wave W33 has an appropriate level of vibration intensity AM_3, an appropriate cutoff height h may be formed.

As an example, by the first closing of the cut-off valve 550, the first pressure wave (W21 in FIG. 8) may be generated at the first closing time point t2, and by the second closing of the cut-off valve 550, a second_first pressure wave (W22 in FIG. 8) having a first phase difference with the first pressure wave (W21 in FIG. 8) may be generated at the second closing time point t4. Accordingly, the first pressure wave (W21 in FIG. 8) and the second_first pressure wave (W22 FIG. 8) overlap each other to generate a third_second pressure wave W23 illustrated in FIG. 11.

Since vibration intensity AM_2 of the third_second pressure wave W23 is excessively low, insufficient cutoff characteristics may appear. Accordingly, the second controller 570 may generate a second_second pressure wave having a second phase difference with the first pressure wave (W21 in FIG. 8) by receiving data on the vibration of the third_second pressure wave W23, for example, the amplitude or frequency, from the sensor 560. In this case, the second phase difference may be different from the first phase difference. Accordingly, the first pressure wave (W21 in FIG. 8) and the second_second pressure wave overlap each other to generate a third_third pressure wave W33 illustrated in FIG. 11.

Since the third_third pressure wave W33 has an appropriate level of vibration intensity AM_3, an appropriate cutoff height h may be formed.

According to some embodiments of the present disclosure, the cutoff characteristics of the treating material may be appropriately controlled without changing the opening and closing speed of the cut-off valve 550. As a result, it is possible to manufacture a semiconductor device including the substrate W having reduced defects. For example, the semiconductor device manufactured according to some embodiments of the present disclosure may be a volatile memory chip such as dynamic random access memory (DRAM) or static RAM (SRAM), or a non-volatile memory chip such as phase-change RAM (PRAM), magneto resistive RAM (MRAM), ferroelectric RAM (FeRAM), resistive RAM (RRAM), or NAND flash memory, or a high bandwidth memory (HBM) memory chip in which a plurality of DRAM memory chips are stacked.

In addition, the semiconductor device may be a fin-type transistor (FinFET) including a fin-type patterned channel region, a transistor including nanowires or nanosheets, or a multi-bridge channel field effect transistor (MBCFET™). Furthermore, the semiconductor device may include a vertical FET, a tunneling FET, or a three-dimensional (3D) transistor. However, the technical

Spirit of the present disclosure is not necessarily limited thereto. The embodiments of the present disclosure have been described above with reference to the accompanying drawings, but the present disclosure may be implemented in various different forms, and those skilled in the art to which the present disclosure pertains may understand that the present disclosure may be implemented in other specific forms without changing the technical spirit or essential features of the present disclosure.

What is claimed is:

1. An apparatus for supplying a treating material, the apparatus comprising:
a nozzle configured to discharge the treating material onto a substrate;
a flow pipe configured to channel the treating material to the nozzle;
a cut-off valve connected to the flow pipe and configured to control the discharge of the treating material through the nozzle;
a first controller configured to control a first opening and closing of the cut-off valve; and
a second controller configured to control a second opening and closing of the cut-off valve,
wherein the second opening and closing of the cut-off valve is performed by the second controller after a delay time has elapsed after the first opening and closing is completed.

2. The apparatus of claim 1, further comprising a sensor disposed at an end portion of the nozzle,
wherein the sensor measures vibration of a pressure wave generated by the second opening and closing of the cut-off valve.

3. The apparatus of claim 1, wherein the second controller controls a timing of the second opening and closing.

4. The apparatus of claim 1, wherein the second controller does not control a speed of the second opening and closing.

5. The apparatus of claim 1, wherein a first pressure wave is generated by the first opening and closing,
wherein a second pressure wave is generated by the second opening and closing, and
wherein the first and second pressure waves overlap each other and a combination of the first pressure wave and the second pressure wave produces a third pressure wave.

6. The apparatus of claim 5, wherein a phase difference between the first pressure wave and the second pressure wave occurs according to the delay time.

7. The apparatus of claim 5, wherein the first pressure wave has a first amplitude,
wherein the second pressure wave has a second amplitude, and
wherein the third pressure wave has a third amplitude different from the first and second amplitudes.

8. The apparatus of claim 5, wherein the third pressure wave is formed by constructive interference of the first and second pressure waves.

9. The apparatus of claim 5, wherein the third pressure wave is formed by destructive interference of the first and second pressure waves.

10. The apparatus of claim 1, wherein the treating material does not include photoresist.

11. An apparatus for supplying a treating material, the apparatus comprising:
a nozzle configured to discharge the treating material onto a substrate;
a flow pipe configured to channel the treating material to the nozzle;
a cut-off valve connected to the flow pipe and configured to control a flow of the treating material by adjusting a flow rate of air;
a sensor disposed at an end portion of the nozzle;
a first controller configured to control a closing speed of the cut-off valve; and
a second controller configured to control an opening time point of the cut-off valve,
wherein a first pressure wave is generated at a first closing time point of the cut-off valve, and
wherein a second pressure wave having a phase difference with respect to the first pressure wave is generated at a second closing time point of the cut-off valve.

12. The apparatus of claim 11, wherein the phase difference is generated by a time difference between the first closing time point and the opening time point of the cut-off valve, and
wherein the second controller is configured to control the opening time point by controlling the phase difference.

13. The apparatus of claim 12, wherein a third pressure wave is formed by a combination of the first and second pressure waves,
wherein the sensor is configured to measure vibration of the third pressure wave, and
wherein the second controller is configured to control the phase difference by receiving data on the vibration of the third pressure wave from the sensor and adjusting the time difference.

14. The apparatus of claim 11, wherein the second controller is configured to control the phase difference so that the first and second pressure waves constructively interfere with each other.

15. The apparatus of claim 11, wherein the second controller is configured to control the phase difference so that the first and second pressure waves destructively interfere with each other.

16. A system for supplying a treating material, the system comprising:
an apparatus supplying the treating material including:
a nozzle configured to discharge the treating material onto a substrate;
a flow pipe configured to channel the treating material to the nozzle;
a cut-off valve connected to the flow pipe and configured to control a discharge of the treating material;
a sensor disposed at an end portion of the nozzle;
a first controller configured to control a closing speed of the cut-off valve; and
a second controller configured to control a closing time point of the cut-off valve,
wherein a first pressure wave is generated by a first closing of the cut-off valve,
wherein a second_first pressure wave having a first phase difference with respect to the first pressure wave is generated by a second closing of the cut-off valve,
wherein the first pressure wave and the second_first pressure wave combine to generate a third_first pressure wave,
wherein the second controller is configured to generate a second_second pressure wave having a second phase that is difference from a phase of the first pressure wave by receiving data on vibration of the third_first pressure wave from the sensor, and
wherein the first pressure wave and the second_second pressure wave combine to generate a third_second pressure wave.

17. The system of claim 16, wherein the first phase difference is generated by a time difference between the closing time point and the opening time point of the cut-off valve.

18. The system of claim 17, wherein the second controller is configured to generate the second_second pressure wave having the second phase difference by receiving data on vibration of the third_first pressure wave from the sensor and adjusting the time difference.

19. The system of claim 16, wherein the second controller is configured to receive data on vibration of the third_first pressure wave and control the first pressure wave and the second_first pressure wave to constructively interfere or destructively interfere with each other.

20. The system of claim 16, wherein the second controller does not control a second closing speed of the cut-off valve.
